(19) United States
(12) Patent Application Publication
(10) Pub. No.: US 2013/0032202 A1
(43) Pub. Date: Feb. 7, 2013

(54) PHOTOCATALYTIC MATERIAL AND GLASS SHEET OR PHOTOVOLTAIC CELL INCLUDING SAID MATERIAL

(71) Applicants: Bernard Nghiem, Arsy (FR); Rosiana Aguiar, Paris (FR)

(72) Inventors: Bernard Nghiem, Arsy (FR); Rosiana Aguiar, Paris (FR)

(73) Assignee: SAINT-GOBAIN GLASS FRANCE, Courbevoie (FR)

(21) Appl. No.: 13/520,165

(22) PCT Filed: Jan. 10, 2011
(86) PCT No.: PCT/FR2011/050033

§ 371 Date: Oct. 24, 2012

(30) Foreign Application Priority Data
Jan. 11, 2010 (FR) 1050142

(51) Int. Cl. B01J 21/06; H01L 31/0216; B32B 17/06

(52) U.S. Cl. 136/256; 502/350; 428/196

(57) ABSTRACT

A material includes a glass substrate provided on at least one portion of one of its faces with a photocatalytic coating based on titanium dioxide that covers at most 15% of the subjacent surface, the photocatalytic coating being in the form of a two-dimensional network of interconnected strands.

The invention relates to the field of materials comprising a glass substrate provided with a photocatalytic coating.

Photocatalytic coatings, especially those based on titanium dioxide, are known for conferring self-cleaning and anti-soiling properties on the substrates that are provided therewith. Two properties are at the origin of these advantageous features. Titanium oxide is first of all photocatalytic, that is to say that it is capable, under suitable radiation, generally ultraviolet radiation, of catalysing the degradation reactions of organic compounds. This photocatalytic activity is initiated within the layer by the creation of an electron-hole pair. Furthermore, titanium dioxide has an extremely pronounced hydrophilicity when it is irradiated by this same type of radiation. This high hydrophilicity, sometimes described as “super-hydrophilicity”, allows mineral soiling to be removed under water runoff, for example rainwater runoff. Such materials, in particular glazing units, are described, for example, in application EP-A-0 850 204.

Titanium dioxide has a high refractive index, which leads to high light reflection factors for substrates provided with photocatalytic coatings. This constitutes a drawback in the field of glazing units for buildings, and even more in the field of photovoltaic cells, for which it is necessary to maximize the transmission to the photovoltaic material, and therefore to minimize all absorption and reflection of solar radiation. There is, however, a need to provide the photovoltaic cells with a photocatalytic coating, since the deposition of soiling is capable of reducing the efficiency of the photovoltaic cells by around 6% per year. This number is obviously dependent on the geographical location of the cells.

In order to reduce the light reflection factor, it is possible to reduce the thickness of the photocatalytic coatings, but this is done to the detriment of their photocatalytic activity.

The objective of the invention is to propose photocatalytic materials based on titanium oxide combining both a high photocatalytic activity and low light reflection factors.

For this purpose, one subject of the invention is a material comprising a glass substrate provided on at least one portion of one of its faces with a photocatalytic coating based on titanium dioxide that covers at most 15% of the subjacent surface, said photocatalytic coating being in the form of a two-dimensional network of interconnected strands.

Another subject of the invention is a process for obtaining a material according to the invention. This preferred process comprises the following steps:
depositing a mask layer on a glass substrate,
drying said mask layer until a two-dimensional network of interstices is obtained,
depositing a coating based on titanium dioxide on the substrate coated with the mask,
removing the mask layer.

The drying of the mask layer, by causing the shrinkage thereof, will create, by cracking, a two-dimensional network of interstices, which will be filled by the titanium dioxide deposited subsequently.

The low coverage by the coating according to the invention makes it possible to considerably reduce the negative impact of the titanium oxide on the light reflection. However, the photocatalytic activity proved to remain high even more since the surface quantity of titanium oxide, partly determined by the height of the strands, may be large. It would appear that the free radicals generated by the photocatalytic action of the titanium oxide had the ability to diffuse over the subjacent surface (not covered by the titanium oxide) over very large distances, ranging up to several micrometres or tens of micrometres. It is thus possible to confer a high photocatalytic activity and a super-hydrophilicity on a surface not covered by the titanium oxide.

Preferably, the substrate is a sheet of glass. The sheet may be flat or curved, and have any type of dimensions, especially greater than 1 metre. The glass is preferably of soda-lime-silica type, but other types of glasses, such as borosilicate glasses or aluminosilicates, may also be used. The glass may be clear or extra-clear, or else tinted, for example tinted blue, green, amber, bronze or grey. The thickness of the glass sheet is typically between 0.5 and 19 mm, in particular between 2 and 12 mm, or even between 4 and 8 mm. In the field of photovoltaic cells, the glass is preferably extra-clear; it preferably comprises a total weight content of iron oxide of at most 150 ppm, or 100 ppm and even 90 ppm, or a redox of at most 0.2, especially 0.1 and even a zero redox. The term “redox” is understood to mean the ratio between the weight content of ferrous iron oxide (expressed in the form FeO) and the total weight content of iron oxide (expressed in the form Fe₂O₃).

Preferably, and for the purpose of minimizing the reflection, the photocatalytic coating covers at most 10%, or 8% or even 5% of the subjacent surface.

The network of strands which constitutes the coating according to the invention (and therefore also the network of interstices) is said to be “two-dimensional” since it extends mainly in the plane of the substrate. As explained in greater detail in the remainder of the text, the strands also have a certain “height”, which corresponds to the thickness of the coating, in the direction orthogonal to the plane of the substrate.

The strands, which form the two-dimensional network constituting the coating according to the invention, are preferably constituted of titanium dioxide. The latter is preferably at least partially crystallized in anatase form, which is the most active form. A mixture of anatase and rutile phases is also possible. The titanium dioxide may be pure or doped, for example doped with transition metals (for example W, Mo, V, Nb), lanthanide ions or noble metals (such as, for example, platinum or palladium), or else with nitrogen, carbon or fluorine atoms. These various doping forms make it possible either to increase the photocatalytic activity of the material, or to shift the band gap of the titanium oxide to wavelengths close to the visible range or within this range.

The two-dimensional network of interconnected strands (and therefore also the two-dimensional network of interstices) is preferably random and/or aperiodic.

The term “strand” is understood to mean a three-dimensional deposit of material, of which one of the dimensions, in the plane of the substrate, referred to as the “length” is much larger than the other dimension located in the plane of the substrate—referred to as the “width”, and than the dimension located in a direction orthogonal to the plane of the substrate, referred to as the “height”.

The width of the strands is preferably between 0.5 and 50 micrometres, in particular between 0.5 and 5 micrometres, or even at most 1 micrometre. When the process according to the invention is used, the width of the strands corresponds to the width of the interstices created in the mask layer by drying.

The height of the strands (therefore the thickness of the photocatalytic coating) is preferably between 5 and 1000 nanometres, in particular between 10 and 150 nm. A high strand height makes it possible to increase the photocatalytic activity of the coating, without however substantially increasing the light reflection, which depends essentially on the surface covered by the coating. The invention is noteworthy in that it makes it possible to obtain substantial thicknesses, and therefore a high photocatalytic activity, despite a low level of coverage, contrary to solutions in which lightly covering coatings have been obtained by virtue of depositions of very small amounts of material. The height of the strands is limited only by the thickness of the mask layer.

The expression “opening of the network” is understood to mean a zone not covered by the photocatalytic coating, delimited by portions of strands, and revealing the subjacent surface. When the process according to the invention is used, the openings of the network correspond to the zones previously covered by the mask layer after drying. Typically, most of the openings of the network are delimited by three, four or five portions of strands. Preferably, at least 80%, or even 90%, of the openings of the network are delimited by four portions of strands. For at least 80% or even 90% of the network openings, the angle formed at each corner by two adjacent strand portions is preferably between 60 and 110°, in particular between 80 and 100°.

The process according to the invention is noteworthy in that it makes it possible to obtain interstices, the walls of which are orthogonal or substantially orthogonal at the surface of the substrate. The angle formed between the walls and the surface of the substrate is typically between 80 and 100°, in particular between 85 and 95°. Therefore, the titanium dioxide deposited subsequently may easily reach the surface of the substrate, even when the width of the interstices is very small. It is therefore possible to obtain very fine strands, the effect of which on the light reflection is extremely limited.

The width and height of the strands (and therefore also of the interstices) are generally homogeneous over the entire surface of the coating. Preferably, the ratio between the maximum width of the strands and the minimum width of the strands is at most 4, in particular at most 2. Likewise, the size of the openings of the network is preferably relatively homogeneous, the surface area ratio between the largest opening and the smallest opening advantageously being at most 4, or at most 2.

An antireflection coating is preferably interposed between the substrate and the photocatalytic coating, which makes it possible further to reduce the reflection factor of the material according to the invention. The expression “antireflection coating” is understood to mean a coating that makes it possible to achieve a light reflection factor lower than that of the substrate. The antireflection coating is normally completely covering, in the sense that it covers the entirety of the surface of the substrate. In the process according to the invention, the antireflection coating will therefore generally be deposited prior to the deposition of the mask layer.

The antireflection coating may be constituted of a stack of layers, alternating between high refractive index layers and low refractive index layers. It may, by way of example, be a stack having four layers of the H/L/H/L type, where each H (high index) layer is for example made of titanium oxide or silicon nitride, and each L (low index) layer is made of silica. In such an interference filter, the indices and the thicknesses of the layers are chosen so as to create destructive interferences. It may especially be a stack described in application WO 01/94989 or WO 2007/077373.

According to a second embodiment, the antireflection coating may be constituted of a layer for which the refractive index is lower than that of the substrate. It is preferably a layer of silica, perfectly compatible with the glass substrates, but other oxides are possible, such as for example the oxides of aluminium, zirconium or else tin. In order to minimize its refractive index, this coating is preferably porous. Its porosity is advantageously between 10 and 80%. The porosity may be open or closed, preferably closed. The pores are preferably mesopores (the average diameter of which is between 2 and 50 nm), or better still macropores (the average diameter of which is preferably between 50 nm and 100 nm). Such pores (mesopores or macropores) may be obtained by a sol-gel process using organometallic precursors of the constituent material of the coating (for example tetraethylorthosilicate—TEOS—in the case of a silica layer) and a pore-forming agent. The pore-forming agent is trapped during the formation of the coating by precipitation and condensation, then is removed during the calcination of the coating thus creating the desired pores. The size, shape and amount of pore-forming agents will therefore directly influence the diameter of the pores, their shape, and the total porosity. Among the pore-forming agents, mention may be made of anionic surfactants, cationic surfactants or else surfactants in the form of block copolymers (such as cetyltrimethylammonium bromide—CTAB—or polyoxyethylene/polyoxypropylene), polymers, especially in the form of beads (for example made of polymethylmethacrylate, polyester, polycarbonate, polypropylene, polystyrene, etc.), or else organic liquid phases self-organised into droplets in a nanoemulsion (for example paraffin oils). The geometric thickness of the antireflection coating is preferably between 10 nm and 10 micrometres, in particular between 50 nm and 1 micrometre, or even between 100 and 200 nm.

According to a third embodiment, the antireflection coating may be constituted by a surface portion of the glass that is partially or completely dealkalinized, in particular by reaction with an acid.

The deposition of the mask layer is preferably carried out using a dispersion of colloidal particles. These particles dispersed in a solvent are deposited on the substrate by processes such as dip coating, spray coating, curtain coating, flow coating or else laminar flow coating. The solvent is removed by drying, causing tensile stresses within the mask layer, which via relaxation form the interstices. After drying the mask layer is constituted of clusters of particles separated by the interstices.

The solvent is preferably predominantly aqueous, or even constituted of water. Various known means may be used, if necessary, to stabilize the dispersion, and thus to avoid the agglomeration of particles: pH control, addition of surfactant, etc.

The mean diameter of the particles in the dispersion and in the mask layer is preferably between 40 and 500 nm, in particular between 50 and 300 nm, and even between 80 and 250 nm.

The concentration of particles in the dispersion is preferably between 5 and 60% by weight, in particular between 20 and 40%.

In a first embodiment, the particles are polymeric, preferably insoluble in water. The polymer is preferably an acrylic polymer or copolymer, for example a styrene/acrylic copolymer. It may also be a polystyrene, polyacrylate, polyester or a blend of these various polymers.

In order to facilitate the formation of the mask during drying, the latter is preferably carried out at a temperature below the glass transition temperature (Tg) of the polymer. The difference with the Tg is preferably at least 10° C., or even 20° C.

In a second embodiment, the particles are inorganic, in particular based on an oxide, for example silica, alumina or else iron oxide.

The drying is preferably carried out at a temperature close to ambient temperature, for example between 20 and 30° C. The drying normally takes place at atmospheric pressure, but may take place under vacuum.

After drying, the network of interstices may be cleaned, for example using a plasma source, at atmospheric pressure.

The photocatalytic coating may then be deposited, via various known techniques, such as sputtering, chemical vapour deposition (CVD), especially plasma-enhanced (PECVD), under vacuum or at atmospheric pressure (APPECVD), evaporation, liquid phase pyrolysis, or else a process of sol-gel type.

In the sputtering process, especially assisted by a magnetic field (magnetron sputtering process), excited species of a plasma extract the atoms from a target located opposite the substrate to be coated. For the deposition of the titanium oxide layer, the target may especially be made of metallic titanium or of TiOₓ, the plasma having to contain oxygen (it is referred to as reactive sputtering).

Chemical vapour deposition, generally denoted by its acronym CVD, is a pyrolysis process using gaseous precursors that decompose under the effect of the heat of the substrate. In the case of titanium oxide, the precursors may be, by way of example, titanium tetrachloride, titanium tetraisopropoxide or titanium tetraorthobutoxide. This type of process will be used when the mask layer can withstand high temperatures, especially when it is of inorganic nature. In the processes PECVD (under vacuum) and APPECVD (under atmospheric pressure), on the other hand, the decomposition of the precursors takes place under the action of a plasma, and not under the effect of the heat, which makes it possible to use mask layers of an organic nature.

The deposition is generally carried out over the entire surface of the substrate coated with its mask layer. Thus, the titanium oxide is deposited both on the surface of the mask layer and in the interstices.

The mask layer is then removed, in order to reveal the two-dimensional network of strands based on titanium oxide.

The removal of the mask layer is preferably carried out using a solvent, for example water, an alcohol or else acetone. The temperature during the removal may be ambient temperature, but slight heating is possible.

The removal step may be followed by a heat treatment, especially of the tempering, bending or annealing type, or by a rapid treatment using laser radiation or a flame, especially when the titanium dioxide layer has been deposited by sputtering. This heat treatment is intended to crystallize the titanium oxide in anatase form. The rapid treatment is preferably a treatment as described in application WO 2008/096089.

The material according to the invention preferably has a light transmission factor (within the meaning of the ISO 9050:2003 standard) of at least 80%, or 85% and even 90%, and/or a light reflection factor (within the meaning of the ISO 9050:2003 standard) of at most 5%, in particular 3%.

Another subject of the invention is glazing or a photovoltaic cell comprising at least one material according to the invention.

The glazing may be single glazing or multiple glazing (especially double or triple glazing), in the sense that it may comprise several glass sheets providing a gas-filled space. The glazing may also be laminated and/or tempered and/or hardened and/or curved.

The other face of the material according to the invention, or where appropriate a face of another substrate of the multiple glazing, may be coated with another functional layer or with a stack of functional layers. It may especially be another photocatalytic layer. It may also be layers or stacks having a thermal function, in particular solar-protection or low-emissivity layers or stacks, for example stacks comprising a silver layer protected by dielectric layers. It may also be a mirror layer, especially based on silver. It may finally be a lacquer or an enamel intended to opacify the glazing in order to make a wall cladding panel therefrom, known as curtain walling. The curtain walling is positioned on the wall at the sides of non-opacified glazing and makes it possible to obtain walls that are entirely glazed and homogenous from an aesthetic point of view.

In the photovoltaic cell according to the invention, the material according to the invention is preferably the substrate of the front face of the cell, that is to say that which is the first passed through by the solar radiation. The photocatalytic coating is then positioned towards the outside, so that the self-cleaning effect can usefully be demonstrated.

For applications as photovoltaic cells, and in order to maximize the energy efficiency of the cell, several improvements may be made, cumulatively or alternately:
The glass sheet may advantageously be coated, on the face opposite the face provided with the coating according to the invention, with at least one thin transparent and electroconductive layer, for example based on SnO₂:F, SnO₂:Sb, ZnO:Al or ZnO:Ga. These layers may be deposited onto the substrate by various deposition processes, such as chemical vapour deposition (CVD) or deposition by sputtering, especially when enhanced by a magnetic field (magnetron sputtering process). In the CVD process, halide or organometallic precursors are vaporized and transported by a carrier gas to the surface of the hot glass, where they decompose under the effect of the heat to form the thin layer. The advantage of the CVD process is that it is possible to use it within the process for forming the glass sheet, especially when it is a float process. It is thus possible to deposit the layer at the moment when the glass sheet is on the tin bath, at the outlet of the tin bath, or else in the lehr, that is to say at the moment when the glass sheet is annealed in order to eliminate the mechanical stresses.
The glass sheet coated with a transparent and electroconductive layer may be, in turn, coated with a semiconductor based on amorphous or polycrystalline silicon, on chalcopyrites (especially of the CIS—CuInSe₂ or CIGS—CuInGaSe₂ type) or on CdTe in order to form a photovoltaic cell. In this case, another advantage of the CVD process lies in obtaining a greater roughness, which generates a light-trapping phenomenon, which increases the amount of photons absorbed by the semiconductor.
The surface of the glass sheet may be textured, for example have motifs (especially pyramid-shaped motifs), as described in Applications WO 03/046617, WO 2006/134300, WO 2006/134301 or else WO 2007/015017. These texturings are in general obtained using a rolling process for forming the glass.

The invention will be better understood in light of the following non-limiting examples.

Deposited, by known sputtering techniques, on a substrate made of 4 mm thick extra-clear glass sold by the Applicant under the trade mark SGG Diamant®, is an antireflection coating constituted of the following four layers (the geometric thickness of each of the layers is indicated between parentheses):

Glass/Si₃N₄ (18 nm)/SiO₂ (23 nm)/Si₃N₄ (115 nm)/SiO₂ (90 nm)

By virtue of the antireflection coating deposited on both faces of the substrate, the light transmission factor is 97.4%.

A mask layer is deposited on this substrate in the following manner.

The colloidal dispersion used is a mixture of 97% of an aqueous dispersion of an acrylic copolymer sold under the name NéoCryl® XK-52 by DSM NeoResins and of 3% of an aqueous dispersion of an acrylic copolymer sold under the name NéoCryl® XK-240 by DSM NeoResins.

The first dispersion is composed of 60% by weight of water and of 40% by weight of particles of an acrylic copolymer, the average diameter of which is around 70 nm. The glass transition temperature of the polymer is 115° C. The viscosity of the dispersion at 25° C. is 15 mPa·s and its pH is 5.1.

The second dispersion is composed of 48% by weight of water and of 52% by weight of particles of an acrylic copolymer, the average diameter of which is around 180 nm (measured by known methods, using light scattering). The glass transition temperature of the polymer is −4° C. The viscosity of the dispersion at 25° C. is 160 mPa·s and its pH is 7.5.

The deposition is carried out by dip coating at a rate of 30 cm per minute. The drying takes place at ambient temperature. The thickness of the mask layer after drying is around 7 to 10 micrometres.

The interstices created by the drying are then cleaned using an N₂/O₂ plasma.

A layer of titanium dioxide is deposited on the substrate provided with the dried mask layer by magnetron sputtering using a target made of metallic titanium, under an argon and oxygen plasma.

The thickness of titanium dioxide obtained (height of the strands) is 50 nm or 100 nm depending on the samples.

The mask layer is then removed using a mixture of demineralized water and ethanol.

The material obtained is then annealed at a temperature of 620° C. for 12 minutes.

Photocatalytic coatings are thus obtained in the form of a network of interconnected strands that extend over the surface of the substrate. Around 10% of the surface is covered with the coating. The width of the strands typically varies between 5 and 15 micrometres.

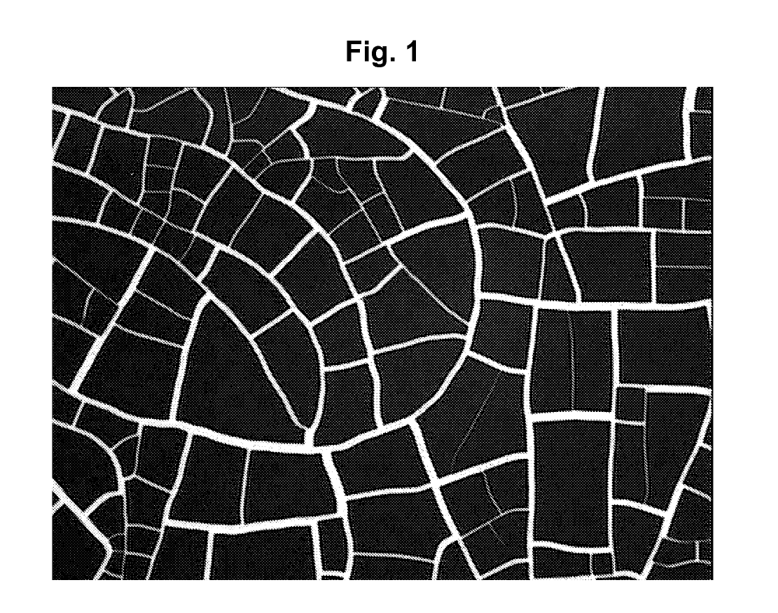

The morphology of the coatings is represented in FIG. 1, as it is seen using an optical microscope. In this figure the network of interconnected strands (in clear) and the openings of the network (in dark) are distinguished.

The drop in the light transmission factor due to the addition of the photocatalytic coating is only 2% (as an absolute value) for the coating having a thickness of 50 nm and 5% for the coating having a thickness of 100 nm. By way of comparison, a completely covering layer of titanium dioxide of the same thickness would result in a drop of around 40%.

The photocatalytic activity is evaluated by virtue of a measurement of the degradation rate of methylene blue in the presence of ultraviolet radiation. An aqueous solution of methylene blue is placed in contact in a leak-tight cell with the coated substrate (the latter forming the base of the cell). After exposure to ultra-violet radiation for 30 minutes, the concentration of methylene blue is evaluated by a light transmission measurement. The photocatalytic activity value (denoted by Kb and expressed in g·l⁻¹·min⁻¹) corresponds to the reduction in the concentration of methylene blue per unit of exposure time. The Kb activity measured for the two samples according to the invention is 11 g·l⁻¹·min⁻¹.

The water contact angle of the samples according to the invention, of the order of 50° to 60° without UV irradiation, changes to 5° after one hour of irradiation. The surface therefore rapidly becomes super-hydrophilic.

1. A material comprising a glass substrate provided on at least a portion of one of face thereof with a photocatalytic coating based on titanium dioxide that covers at most 15% of a subjacent surface, said photocatalytic coating being in the form of a two-dimensional network of interconnected strands.

2. The material according to claim 1, wherein the network is random and aperiodic.

3. The material according to claim 1, wherein a width of the strands is between 0.5 and 50 micrometers.

4. The material according to claim 1, wherein a height of the strands is between 5 and 1000 nanometers.

5. The material according to claim 1, wherein at least 80% of the openings of the network are delimited by four portions of strands.

6. The material according to claim 1, wherein an antireflection coating is interposed between the substrate and the photocatalytic coating.

7. A glazing or photovoltaic cell comprising at least one material according to claim 1.

8. A process for obtaining a material according to claim 1, the process comprising:
depositing a mask layer on a glass substrate,
drying said mask layer until a two-dimensional network of interstices is obtained,
depositing a coating based on titanium dioxide on the substrate coated with the mask,
removing the mask layer.

9. The process according to claim 8, wherein the deposition of the mask layer is carried out using a dispersion of colloidal particles.

10. The process according to claim 8, wherein the coating based on titanium dioxide is deposited by sputtering.

11. A material comprising:
a glass substrate, and
a photocatalytic coating in the form of a network of interconnected strands based on titanium dioxide and provided on a portion of a surface of the glass substrate, said interconnected strands covering at most 15% of the portion of the surface underlying the photocatalytic coating.

12. The material according to claim 11, wherein the network is random and aperiodic.

13. The material according to claim 11, wherein a width of the strands is between 0.5 and 50 micrometers.

14. The material according to claim 11, wherein a height of the strands is between 5 and 1000 nanometers.

15. The material according to claim 11, wherein at least 80% of openings of the network are delimited by four portions of strands.

16. The material according to claim 11, wherein an antireflection coating is interposed between the substrate and the photocatalytic coating.
